(19) United States
(12) Patent Application Publication
(10) Pub. No.: US 2025/0176394 A1
(43) Pub. Date: May 29, 2025

(54) DISPLAY PANEL AND DISPLAY APPARATUS

(71) Applicants: Wuhan Tianma Microelectronics Co., Ltd. Shanghai Branch, Shanghai (CN); Wuhan Tianma Microelectronics Co., Ltd., Wuhan (CN)

(72) Inventor: Linqian LIU, Shanghai (CN)

(21) Appl. No.: 19/035,935

(22) Filed: Jan. 24, 2025

(30) Foreign Application Priority Data
Jul. 29, 2024 (CN) 202411031262.4

(51) Int. Cl. H10K 59/35; H10K 59/131

(52) U.S. Cl. CPC H10K 59/353; H10K 59/131

(57) ABSTRACT

Provided is a display panel and a display apparatus. The display panel includes first color sub-pixels, second color sub-pixels and third color sub-pixels, a transmittance of a first display area is larger than that of a second display area. In the first display area, two first color sub-pixels and one second color sub-pixel form a first virtual triangle, and the second color sub-pixel is located on a first side between the two first color sub-pixels in the first virtual triangle, two second color sub-pixels and one third color sub-pixel form a second virtual triangle, the third color sub-pixel is located on a second side between the two second color sub-pixels in the second virtual triangle, the first virtual triangles and the second virtual triangles are alternately arranged in a first direction, and the first virtual triangles and the second virtual triangles are alternately arranged in a second direction.

### CROSS-REFERENCE TO RELATED APPLICATION

The present application claims priority to Chinese Patent Application No. 202411031262.4, filed on Jul. 29, 2024, the content of which is incorporated herein by reference in its entirety.

### TECHNICAL FIELD

The present disclosure relates to the technical field of display, and in particular, to a display panel and a display apparatus.

### BACKGROUND

With the development of display technology, the scheme of under-display camera is also one of the solution schemes for full screen. The scheme of under-display camera means that a camera is provided under a display screen, and when applied, the camera receives the light transmitted through the display screen for imaging. In order to improve the imaging effect of the under-display camera, it is necessary to ensure that a display area corresponding to the camera has a large transmittance. At present, solutions to reduce the number of sub-pixels in the display area corresponding to the camera are adopted to improve the transmittance, but the existing solutions may cause horizontal and vertical display misalignment of the display area corresponding to the camera, and thus affect the display effect.

### SUMMARY

Embodiments of the present disclosure provides a display panel and a display apparatus to solve the technical problem to improve the display effect.

In a first aspect, an embodiment of the present disclosure provides a display panel including a plurality of sub-pixels including first color sub-pixels, second color sub-pixels and third color sub-pixels; and a display area including a first display area and a second display area. A transmittance of the first display area is greater than a transmittance of the second display area.

In the first display area:

Two first color sub-pixels and one second color sub-pixel are respectively located at positions of three vertexes of a first virtual triangle, and another one second color sub-pixel is located on a first side between the two first color sub-pixels in the first virtual triangle; and an angle opposite to the first side in the first virtual triangle is a first angle.

Two second color sub-pixels and one third color sub-pixel are respectively located at positions of three vertexes of a second virtual triangle, and another one third color sub-pixel is located on a second side between the two second color sub-pixels in the second virtual triangle; an angle opposite to the second side in the second virtual triangle is a second angle; and an orientation of the second angle is opposite to an orientation of the first angle.

A plurality of first virtual triangles and a plurality of second virtual triangles are alternately arranged in a first direction, a plurality of first virtual triangles and a plurality of second virtual triangles are alternately arranged in a second direction, and the first direction and the second direction intersect with each other.

In a second aspect, based on the same inventive concept, an embodiment of the present disclosure further provides a display apparatus including the display panel according to any of the embodiments of the present disclosure.

The display panel and the display apparatus according to the embodiments of the present disclosure have the following beneficial effects: when the sub-pixel rendering mode is adopted for display or the sub-pixel rendering mode is closed for display, the centers of the display pixels in the first display area and the centers of the display pixels in the second display area may be located on substantially the same horizontal line or located on substantially the same vertical line. As a result, the horizontal and vertical display misalignment of the first display area and the second display area can be alleviated, and thus the display effect can be improved.

### BRIEF DESCRIPTION OF DRAWINGS

In order to more clearly illustrate the embodiments of the present disclosure or the technical solutions in the prior art, the following will briefly introduce the drawings required to be used in the description of the embodiments or the prior art. Obviously, the drawings in the following description are some embodiments of the present disclosure. Those of ordinary skill in the art may still derive other drawings from these drawings without creative efforts.

FIG. 1A is a schematic diagram of a display panel in the related art;

FIG. 1B is a partial enlarged schematic diagram of a display area in FIG. 1A;

FIG. 2 is a schematic diagram of a display panel according to an embodiment of the present disclosure;

FIG. 3 is a schematic diagram of another display panel according to an embodiment of the present disclosure;

FIG. 4A is a partial schematic diagram of another display panel according to an embodiment of the present disclosure;

FIG. 4B is a schematic diagram of another display panel according to an embodiment of the present disclosure;

FIG. 4C is a schematic diagram of another display panel according to an embodiment of the present disclosure;

FIG. 5A is a cross-sectional schematic diagram at the location of a tangent line A-A′ in FIG. 4B;

FIG. 5B is another cross-sectional schematic diagram at the location of the tangent line A-A′ in FIG. 4B;

FIG. 6A is a schematic diagram of another display panel according to an embodiment of the present disclosure;

FIG. 6B is a schematic diagram of another display panel according to an embodiment of the present disclosure;

FIG. 7 is a schematic diagram of another display panel according to an embodiment of the present disclosure;

FIG. 8 is a schematic diagram of another display panel according to an embodiment of the present disclosure;

FIG. 9 is a schematic diagram of another display panel according to an embodiment of the present disclosure;

FIG. 10 is a schematic diagram of another display panel according to an embodiment of the present disclosure;

FIG. 11 is a schematic diagram of another display panel according to an embodiment of the present disclosure; and

FIG. 12 is a schematic diagram of a display apparatus according to an embodiment of the present disclosure.

### DESCRIPTION OF EMBODIMENTS

In order to make the purposes, technical solutions and advantages of the embodiments of the present disclosure more clear, the technical solutions in the embodiments of the present disclosure will be clearly and completely described below in conjunction with the drawings in the embodiments of the present disclosure. Obviously, the described embodiments are part of the embodiments of the present disclosure, but not all of the embodiments. Based on the embodiments of the present disclosure, all other embodiments obtained by those of ordinary skill in the art without creative work are within the scope of the present disclosure.

The term used in the embodiments of the present disclosure is for the purpose of describing particular embodiments only and is not intended to limit the present disclosure. Words, such as “a”, “the”, and “said”, in a singular form used in the embodiments and the append claims of the present disclosure are also intended to include plural form unless the context clearly dictates otherwise.

It should be understood that although the terms “first” and “second” may be used to describe XX in the embodiments of the present disclosure, these XXs should not be limited by these terms. These terms are used only to distinguish XXs from each other. For example, the first XX may also be referred to as the second XX, and similarly, the second XX may also be referred to as the first XX, without departing from the scope of the embodiments of the present disclosure.

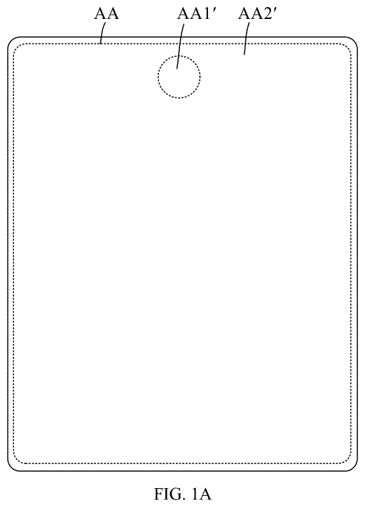

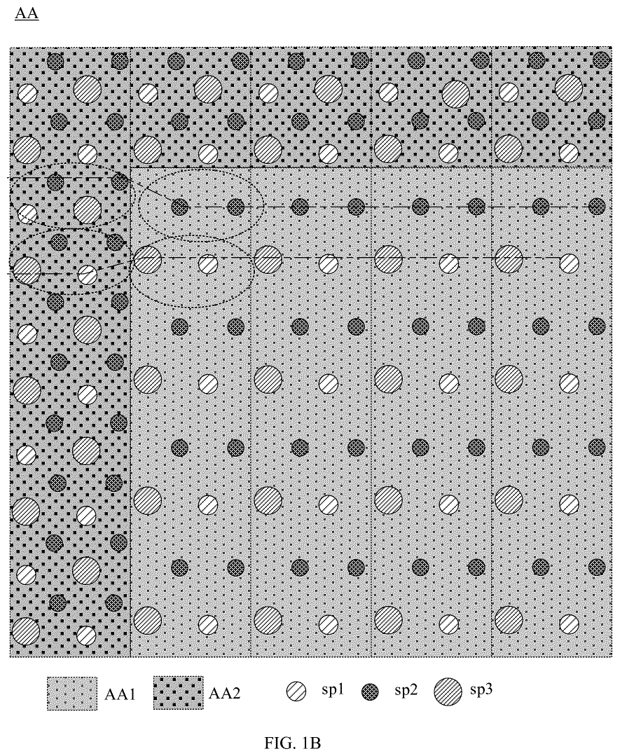

FIG. 1A is a schematic diagram of a display panel in the related art, and FIG. 1B is a partial enlarged schematic diagram of a display area in FIG. 1A. As shown in FIG. 1A, the display area AA of the display panel includes a first display area AA1′ and a second display area AA2′. A transmittance of the first display area AA1′ is greater than a transmittance of the second display area AA2′. When the photosensitive device is applied, a photosensitive device is provided under the first display area AA1′, so that the screen-to-body ratio can be increased. As shown in FIG. 1B, the display area AA includes first color sub-pixels sp1, second color sub-pixels sp2, and third color sub-pixels sp3 therein. A sub-pixel density in the first display area AA1′ is less than a sub-pixel density in the second display area AA2′. For example, the first color sub-pixels sp1 are red sub-pixels R, the second color sub-pixels sp2 are green sub-pixels G, and the third color sub-pixels sp3 are blue sub-pixels B.

It can be seen from FIG. 1B that a RGBG arrangement region in the second display area AA2′ corresponds to a GG or RB arrangement region in the first display area AA1′. The sub-pixels in the first display area AA1′ and the second display area AA2′ are arranged in substantially the same manner, but the spacing between the sub-pixels in a vertical direction in the first display area AA1′ is larger. Optionally, the spacing between the sub-pixels in a horizontal direction in the first display area AA1′ may also be set to be larger, so that the transmittance can be increased. As illustrated by a dotted line in FIG. 1B, the first color sub-pixels sp1 in the first display area AA1′ and the first color sub-pixels sp1 in the second display area AA2′ are not on a same horizontal straight line, the second color sub-pixels sp2 in the first display area AA1′ and the second color sub-pixels sp2 in the second display area AA2′ are not on a same horizontal straight line, and the third color sub-pixels sp3 in the first display area AA1′ and the third color sub-pixels sp3 in the second display area AA2′ are not in a same horizontal straight line. The sub-pixels of the same color are misaligned at the junction location of the first display area AA1′ and the second display area AA2′. When a single color is displayed, or the mixed light is displayed as white, a display step may exist at the junction location of the first display area AA1′ and the second display area AA2′, so that the horizontal/vertical display misalignment occurs in the two display areas, and thus affects the overall display effect. In addition, color shift in display may occur when the sub-pixel rendering mode is used for display.

To solve the above technical problem, the embodiments of the present disclosure are designed for the arrangement of the sub-pixels in the first display area, so as to alleviate the problem of the horizontal and vertical display misalignment of the two display areas and thus improve the display effect.

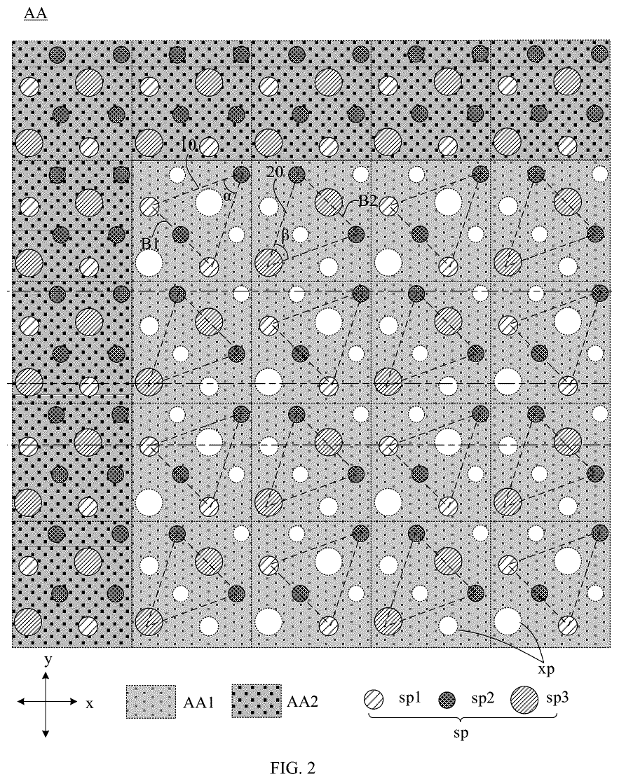

FIG. 2 is a schematic diagram of a display panel according to an embodiment of the present disclosure, and FIG. 2 illustrates a partial area of the display panel. As shown in FIG. 2, the display panel includes a plurality of sub-pixels sp including first color sub-pixels sp1, second color sub-pixels sp2 and third color sub-pixels sp3; the display area AA of the display panel includes a first display area AA1 and a second display area AA2, and a transmittance of the first display area AA1 is greater than a transmittance of the second display area AA2. In an embodiment of present disclosure, the transmittance of the first display area AA1 is increased by reducing the sub-pixel density in the first display area AA1. The display panel according to the embodiment of the present disclosure can be applied to the scheme of under-display photosensitive device, and a photosensitive device (for example a camera and an infrared sensor) is arranged below the first display area AA1, so that the screen-to-body ratio of the electronic product can be improved.

In the first display area AA1:

Two first color sub-pixels sp1 and one second color sub-pixel sp2 are respectively located at positions of three vertexes of a first virtual triangle 10, and one second color sub-pixel sp2 is located on a first side B1 between the two first color sub-pixels sp1 in the first virtual triangle 10. The angle opposite to the first side B1 in the first virtual triangle 10 is a first angle α.

Two second color sub-pixels sp2 and one third color sub-pixel sp3 are respectively located at positions of three vertexes of a second virtual triangle 20, and one third color sub-pixel sp3 is located on a second side B2 between the two second color sub-pixels sp2 in the second virtual triangle 20. The angle opposite to the second side B2 in the second virtual triangle 20 is the second angle β. An orientation of the second angle β is opposite to an orientation of the first angle α. Each of the three sides of the first virtual triangle 10 form a non-zero included angle with a first direction y, and each of the three sides of the second virtual triangle 20 form a non-zero included angle with the first direction y.

The first virtual triangles 10 and the second virtual triangles 20 are alternately arranged along the first direction y. The first virtual triangles 10 and the second virtual triangles 20 are alternately arranged in a second direction x. The first direction y and the second direction x intersect each other. In an embodiment, the first direction y and the second direction x are perpendicular to each other. In the first display area AA1, two first virtual triangles 10 and two second virtual triangles 20 form a repeating unit. In the repeating unit, the two first virtual triangles 10 are located at diagonal positions and the two second virtual triangles 20 are located at diagonal positions.

In FIG. 2, the virtually provided sub-pixel areas XP are illustrated by dotted lines, and if arranged in accordance with the arrangement of the sub-pixels in the second display area AA2, sub-pixels will be correspondingly provided in the virtually provided sub-pixel areas XP. In FIG. 2, a plurality of units are defined by intersecting horizontal and vertical dotted lines, and the area of one unit in the second display area AA2 is substantially equal to the area of one unit in the first display area AA1. There are 8 sub-pixels sp in one unit in the second display area AA2 and only 4 sub-pixels sp in one unit in the first display area AA1, whereby the transmittance of the first display area AA1 is increased. One unit in the second display area AA2 includes two first color sub-pixels sp1, two third color sub-pixel sp3, and four second color sub-pixels sp2. A unit in which the first virtual triangle 10 is located includes two first color sub-pixels sp1 and two second color sub-pixels sp2, and a unit in which the second virtual triangle 20 is located includes two third color sub-pixels sp3 and two second color sub-pixels sp2. As such, the unit in which the first virtual triangle 10 is located is equivalent to a unit which is obtained by removing two third color sub-pixels sp3 and two second color sub-pixels sp2 from a unit in the second display area AA2. The unit in which the second virtual triangle 20 is located is equivalent to a unit which is obtained by removing four second color sub-pixels sp2 from a unit in the second display area AA2. The sub-pixel density in the first display area AA1 is half of the sub-pixel density in the second display area AA2.

In an embodiment of the present disclosure, the arrangement of the sub-pixels in the first display area AA1 is equivalent to removing some of the sub-pixels sp based on the arrangement of the sub-pixels in the second display area AA2. The individual sub-pixels in the first display area AA1 have a certain relative positional relationship, and the same relative positional relationship of the sub-pixels as the relative positional relationship of the sub-pixels in the first display area AA1 can be found in the second display area AA2. As can be seen from FIG. 2, in one pixel row, the first-color sub-pixels sp1 in the first display area AA1 and the first-color sub-pixels sp1 in the second display area AA2 are substantially located on the same straight line extending along the second direction x. The second color sub-pixel sp2 in the first display area AA1 and the second color sub-pixel sp2 in the second display area AA2 are substantially located on the same straight line extending along the second direction x. The third color sub-pixel sp3 in the first display area AA1 and the third color sub-pixel sp3 in the second display area AA2 are substantially located on the same straight line extending along the second direction x. That is, the sub-pixels of the same color in the two areas are substantially free of misalignment along the second direction x. Moreover, in an embodiment of the present disclosure, the sub-pixels of the same color in the two areas are substantially free of misalignment along the first direction y. When a single color is displayed, or the mixed colors is displayed as white, the centers of the display pixels in the two areas are substantially located on the same horizontal line or the same vertical line. No matter whether the sub-pixel rendering mode is used for display or the sub-pixel rendering mode is closed for display, the centers of the display pixels in the first display area AA1 and the centers of the display pixels in the second display area AA2 are substantially located on the same horizontal line or located on substantially the same vertical line. In this way, the display misalignment between the first display area AA1 and the second display area AA2 in the horizontal direction and the vertical direction can be alleviated, and thus the display effect can be improved.

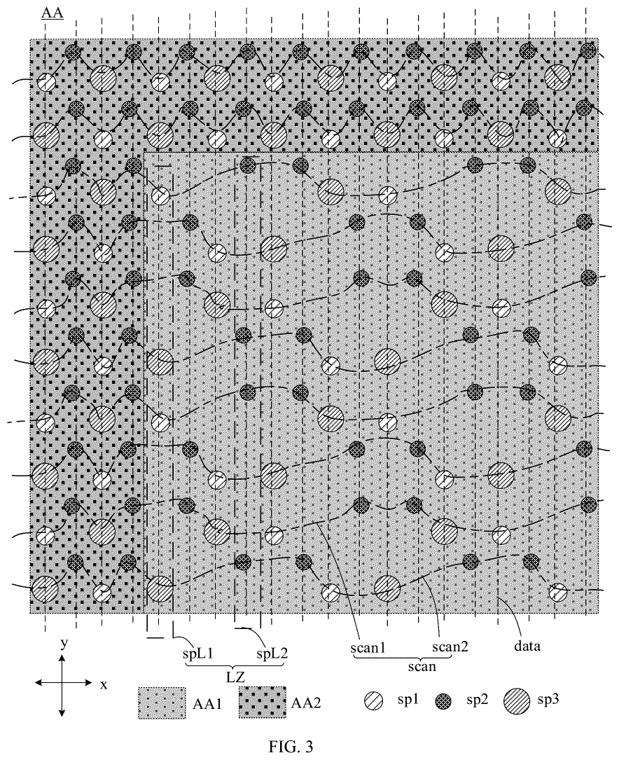

In some implementations, FIG. 3 is a schematic diagram of another display panel according to an embodiment of the present disclosure. As shown in FIG. 3, in the first display area AA1: the first color sub-pixels sp1 and the third color sub-pixels sp3 are alternately arranged along the first direction y to form first pixel columns spL1, and the second color sub-pixels sp2 are arranged along the first direction y to form second pixel columns spL2; and the first pixel columns spL1 and the second pixel columns spL2 are alternately arranged along the second direction x. The display panel includes a plurality of data lines data. The first color sub-pixels sp1 and the third color sub-pixels SP3 in a first pixel column spL1 are electrically connected to a same data line, and a plurality of second color sub-pixels sp2 in a second pixel column spL1 are electrically connected to another same data line. FIG. 3 merely schematically illustrates the connection relationship between the data lines data and the sub-pixels sp, but does not represent the actual wiring of the data lines data. For example, FIG. 3 shows that the data lines data extend into the first display area AA1 along the first direction y. In fact, however, the pixel circuits corresponding to the sub-pixels sp in the first display area AA1 may also be provided outside the first display area AA1. As such, the driving of the sub-pixels in the first display area AA1 can be realized by connecting the data lines data to the respective pixel circuits located outside the first display area AA1, without extending the data lines data into the first display area AA1. In this way, the transmittance of the first display area AA1 can be improved.

For example, the first color sub-pixels sp1 are red sub-pixels R, the second color sub-pixels sp2 are green sub-pixels G, and the third color sub-pixels sp3 are blue sub-pixels B. As can be seen from FIG. 3, the arrangement sequence of the sub-pixels connected to the data line data which are located in the second display area AA2 is RBRB . . . or GG . . . . The arrangement sequence of the sub-pixels connected to the data line data which are located in the first display area AA1 is RBRB . . . or GG . . . . It can be seen that the corresponding connection relationship between the sub-pixels sp and the data line data in the first display area AA1 is the same as that in the second display area AA2. For example, a kind of data line data can simultaneously drive the sub-pixels in the first display area AA1 and the second display area AA2 by alternately supplying an R data voltage and a B data voltage, and another kind of data line data can simultaneously drive the sub-pixels in the first display area AA1 and the second display area AA2 by continuously supplying a G data voltage. In the embodiments of the present disclosure, it can be ensured that the sub-pixels connected to a data line data can be normally driven by the data line data.

In some implementations, as shown in FIG. 3, the display panel includes a plurality of scan lines scan including first scan lines scan1 and second scan lines scan2; the plurality of sub-pixels sp on the first virtual triangles 10 and the second virtual triangles 20 alternately arranged along the second direction x are correspondingly connected to one first scan line scan1 and one second scan line scan2. The connection relationship between each scan line scan and the sub-pixels sp can be understood with reference to the positions of the first virtual triangle 10 and the second virtual triangle 20 indicated in FIG. 2.

One of the first color sub-pixels sp1 located on the first side B1, a second color sub-pixel sp2 located at the first angle α, one of the second color sub-pixels sp2 located on the second side B2, and a third color sub-pixel sp3 located on the second side B2 are electrically connected to the first scan line scan1 in sequence; and the second color sub-pixel sp2 located on the first side B1, another one of the first color sub-pixels sp1 located on the first side B1, the third color sub-pixel sp3 located at the second angle β, and another one of the second color sub-pixels sp2 located on the second side B2 are electrically connected to the second scan line scan2 in sequence.

FIG. 3 only illustrates the connection relationship between the scan lines scan and the sub-pixels sp, and does not represent the actual wiring of the scan lines scan. For example, FIG. 3 illustrates that the scan lines scan extend into the first display area AA1 along the second direction x, and in fact, the pixel circuits corresponding to the sub-pixels in the first display area AA1 may be provided outside the first display area AA1. As such, the driving of the sub-pixels in the first display area AA1 can be realized by connecting the scan lines scan to the respective pixel circuits located outside the first display area AA1 without the need for extending the scan line scan into the first display area AA1. In this way, the transmittance of the first display area AA1 can be improved.

For example, the first color sub-pixels sp1 are red sub-pixels R, the second color sub-pixels sp2 are green sub-pixels G, and the third color sub-pixels sp3 are blue sub-pixels B. When the sub-pixels sp in the first display area AA1 in FIG. 3 are viewed from left to right, the sub-pixels connected in sequence to the first scan line scan1 are RGGBRGGB . . . . The sub-pixels connected in sequence to the second scan line scan2 are GRBGGRBG . . . . In the second display area AA2, the sub-pixels connected in sequence to the scan line are RGBGRGBG . . . . It can be seen that one scan line connecting the sub-pixels sp in the first display area AA1 is simultaneously connected to the red sub-pixels R, the green sub-pixels G, and the blue sub-pixels B, and a scan line connecting the sub-pixels sp in the second display area AA2 is also simultaneously connected to the red sub-pixels R, the green sub-pixels G, and the blue sub-pixels B. As such, one scan line can simultaneously drive the sub-pixels in the first display area AA1 and the second display area AA2. According to the embodiments of the present disclosure, it can be ensured that the sub-pixels connected to a scan line scan can be normally driven by the scan line scan.

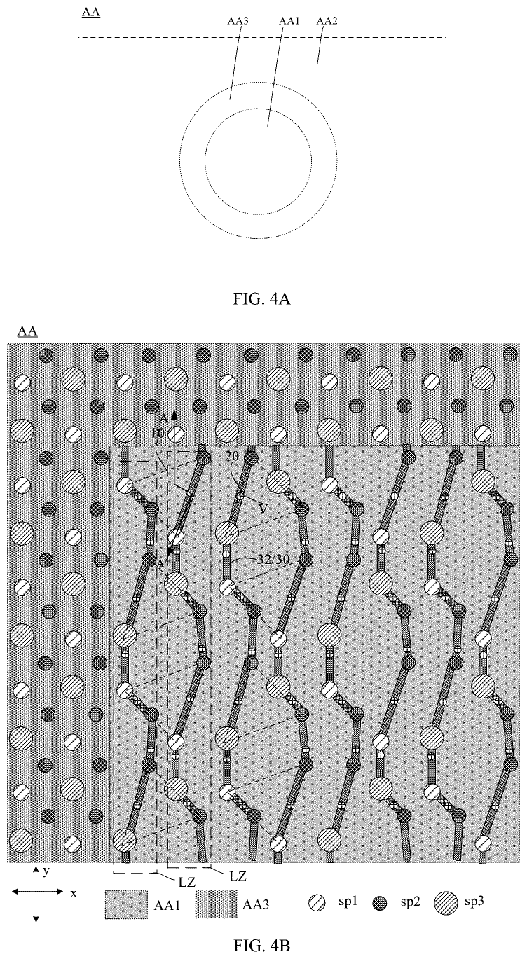

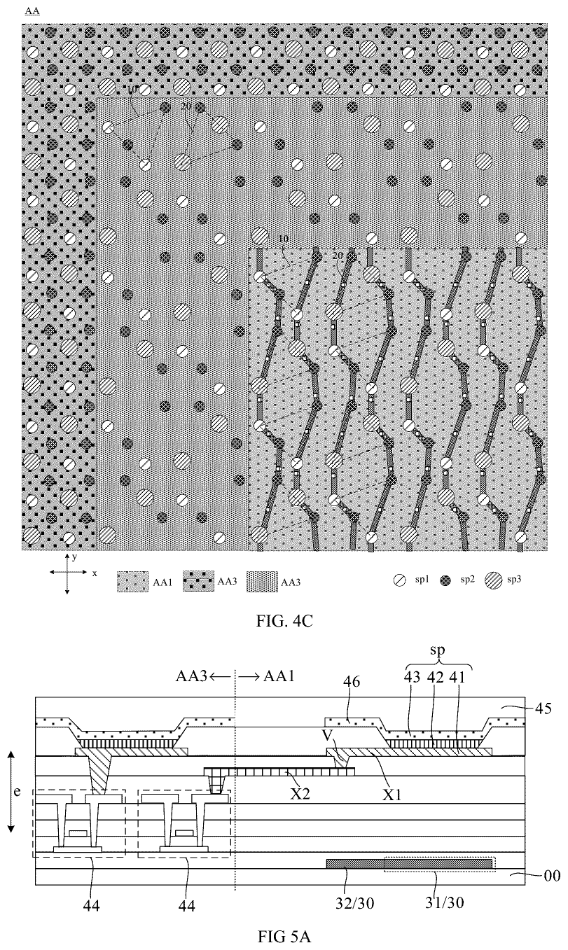

In some implementations, FIG. 4A is a partial schematic diagram of another display panel according to an embodiment of the present disclosure. As shown in FIG. 4A, the display area AA includes a transition area AA3 located between the first display area AA1 and the second display area AA2.

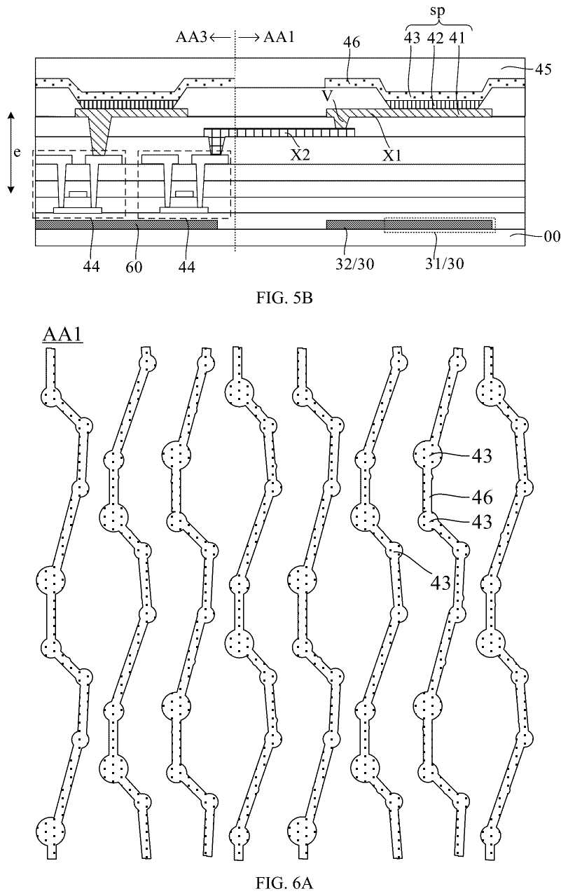

FIG. 4B is a schematic diagram of another display panel according to an embodiment of the present disclosure. FIG. 4B illustrates partial positions of the first display area AA1 and the transition area AA3. FIG. 4C is a schematic diagram of another display panel according to an embodiment of the present disclosure, as shown in FIG. 4C. FIG. 5A is a cross-sectional schematic diagram at the location of the tangent line A-A′ in FIG. 4B.

As seen in conjunction with FIGS. 4B and 5A, the display panel includes a substrate 00, and the sub-pixel sp includes a first electrode 41, a light emitting layer 42, and a second electrode 43 stacked over the substrate 00. The second electrode 43 is arranged on a side of the first electrode 41 away from the substrate 00. In an embodiment, the first electrode 41 is an anode, the second electrode 43 is a cathode, and the light emitting layer 42 includes an organic light-emitting material. An encapsulation layer 45 is provided at a side of the sub-pixel sp away from the substrate 00. The encapsulation layer 45 is configured for protecting the sub-pixel sp. The encapsulation layer 45 includes at least one organic encapsulation layer and at least one inorganic encapsulation layer. The first display area AA1 includes a light-shielding pattern 30 arranged at a side of the sub-pixel sp close to the substrate 00. The light-shielding pattern 30 includes a main body portion 31 and a connecting portion 32. The main body portion 31 and the connecting portion 32 are manufactured in the same layer and the same process. In a direction e perpendicular to a plane in which the substrate 00 is located, the main body portion 31 overlaps with the light emitting layer 42. At least one connecting portion 32 is connected between at least two main body portions 31. FIG. 4B is a top view. The main body portion 31 is not shown in FIG. 4B. It can be understood that the main body portion 31 overlaps with the sub-pixel sp, and the main body portion 31 is located at the location of the sub-pixel sp in FIG. 4B.

In an embodiment of the present disclosure, the light-shielding pattern 30 is provided in the first display area AA1. The light-shielding pattern 30 is located on the side of the sub-pixel sp close to the substrate 00, the main body portion 31 in the light-shielding pattern 30 overlaps with the light emitting layer 42 in the sub-pixel sp, and the main body portion 31 and the connecting portion 32 are connected to each other. In a laser technology, when the display panel is irradiated from a side of the substrate 00 away from the light-shielding pattern 30 to process some film layers, the light-shielding pattern 30 can shield and protect the area with which the light-shielding pattern 30 overlaps, and the film layers which are not shielded by the light-shielding pattern 30 can be removed by laser, whereby the transmittance of the first display area AA1 can be improved after the film layers in a partial region in the first display area AA1 is removed. When the photosensitive device is applied in the scheme of the under-display photosensitive device, the optical performance of the photosensitive device can be improved.

FIG. 4B illustrates that the arrangement of the sub-pixels in the transition region AA3 is different from the arrangement of the sub-pixels in the first display area AA1. In an embodiment, the arrangement of the sub-pixels in the transition area AA3 is the same as the arrangement of the sub-pixels in the second display area AA2, and in this case, the difference between the transition area AA3 and the second display area AA2 lie in that the arrangement densities of the pixel circuits are different.

In another embodiment, as shown in FIG. 4C, the arrangement of the sub-pixels in the transition area AA3 is the same as the arrangement of the sub-pixels in the first display area AA1, whereby the wiring space in the transition area AA3 can be increased, and more advantageously, the pixel circuits 44 for driving the sub-pixels in the first display area AA1 are provided in the transition area AA3.

In the figures of some embodiments described below, only the first display area AA1 and the second display area AA2 are illustrated, and the transition area AA3 is not illustrated.

In some implementations, as shown in FIG. 5A, the display panel further includes a plurality of pixel circuits 44 which are located on a side of the light-shielding pattern 30 away from the substrate 00, the pixel circuits 44 is electrically connected to at least one sub-pixel sp, and the pixel circuits 44 electrically connected to the sub-pixels sp in the first display area AA1 are located in the transition area AA3. The sub-pixels sp located in the first display area AA1 are electrically connected to the pixel circuits 44 through signal connection holes V. In the direction e perpendicular to the plane of the substrate 00, the signal connection holes V overlap with the connecting portions 32. In an embodiments of the present disclosure, the pixel circuits 44 connected to the sub-pixels sp in the first display area AA1 are provided in the transition area AA3, and the signal connection holes V are provided to overlap with the connecting portions 32, so that the transmittance of the first display area AA1 can be further improved.

FIG. 5A is merely a simplified schematic of the pixel circuits 44, and just shows one transistor in the pixel circuits 44. In the embodiments of the present disclosure, the pixel circuits 44 can be any one in the prior art.

As shown in FIG. 5A, the first display area AA1 includes first signal lines X1 and second signal lines X2. The first signal lines X1 and the first electrode 41 are connected to each other and located in a same layer. The material which the second signal lines X2 are made of includes a transparent material. One end of a second signal line X2 is electrically connected to a first signal line X1 through a signal connection hole V, and the other end of the second signal line X2 is connected to a the pixel circuit 44. In the direction e perpendicular to the plane of the substrate 00, each of the first signal lines X1 overlaps with the connecting portion 32. In the implementation, a signal from a pixel circuit 44 is introduced to the first display area AA1 via a second signal line X2, and is connected to the second signal line X2 via a first signal line X1 through a signal connection hole V, so that the connection between the pixel circuit 44 and the sub-pixel sp is realized. The second signal lines X2 are made of a transparent material, and the first signal lines X1 overlaps with the connecting portion 32, so that it can be ensured that the transmittance of the first display area AA1 is not affected.

In another embodiment, FIG. 5B is another cross-sectional schematic diagram at the location of the tangent line A-A′ in FIG. 4B. As shown in FIG. 5B, a light-shielding layer 60 is provided in the transition region AA3, and the light-shielding layer 60 is arranged between the substrate 00 and the pixel circuits 44. The light-shielding layer 60 is configured to shield the channels of the transistors in the pixel circuits 44 from light, so as to ensure stable characteristics of the transistors. In an embodiment of the present disclosure, the light-shielding layer is also provided within the second display area AA2. In an embodiment, in the direction perpendicular to the plane of the substrate, the light-shielding layer 60 overlaps with the channels of the drive transistors in the pixel circuits 44. In other implementations, the light-shielding layer 60 is provided under all of the transistors in the pixel circuits 44.

In an embodiment, the light-shielding layer 60 and the light-shielding pattern 30 are made of a same material and provided in a same layer. The light-shielding pattern 30 is electrically connected to the light-shielding layer 60 through a connecting line, and is connected to a fixed potential.

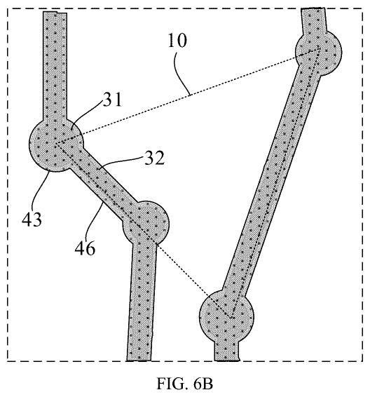

In some implementations, FIG. 6A is a schematic diagram of another display panel according to an embodiment of the present disclosure, and FIG. 6A illustrates a partial pattern of a film layer of the second electrodes 43 in the first display area AA1 in the embodiment in FIG. 4B. As shown in FIG. 6A, the first display area AA1 includes second electrodes 43 and electrode connecting lines 46 located in the same layer as the second electrodes 43, and the electrode connecting line 46 and the second electrode 43 are connected to each other and manufactured in a same process. The shape of the second electrodes 43 is substantially the same as the shape of the sub-pixels sp in FIG. 4B. The size of the third color sub-pixel sp3 illustrated in FIG. 4B is larger than the size of the first color sub-pixel sp1. Accordingly, in FIG. 6A, the size of the second electrode 43 corresponding to the third color sub-pixel sp3 is larger than the size of the second electrode 43 corresponding to the first color sub-pixel sp1. As can be seen from FIG. 5A, in the direction e perpendicular to the plane of the substrate 00, the second electrode 43 overlaps with the main body portion 31, and the electrode connecting line 46 overlaps with the connecting portion 32. In the first display area AA1, the orthographic projections of the second electrode 43 and the electrode connecting line 46 on a film layer of the light-shielding pattern 30 cover the light-shielding pattern 30. When manufacturing the display panel, firstly, an entire layer of second electrode layer is manufactured, and the second electrodes 43 are connected to each other in a planar shape in the first display area AA1. Then, in a laser process, the display panel is irradiated from the side of the substrate 00 away from the light-shielding patterns 30 to process the second electrode layer. The light-shielding patterns 30 can shield and protect the areas which the light-shielding patterns 30 overlap with, and the film layer which is not shielded by the light-shielding patterns 30 is removed by laser. Finally, in this way, the second electrode layer is formed into the second electrodes 43 and the electrode connecting lines 46 as shown in FIG. 6A. Such a configuration can not only ensure the electrical connection between the second electrodes 43 in the first display area AA1, but also improve the transmittance of the first display area AA1 after removing a part of the second electrode layer. When the photosensitive device is applied in the scheme of under-display photosensitive device, the optical performance of the photosensitive device can be improved.

In addition, in the laser process, a laser is irradiated from the side of the substrate 00 to the side of the sub-pixels sp. Due to the influence of the light refraction, scattering and the like, the area of the second electrodes 43 is slightly larger than the area of the main body portion 31 overlapping with the second electrode 43, and the line width of the electrode connecting line 46 may be slightly larger than the width of the connecting portion 32 overlapping with the electrode connecting line 46. In an embodiment, the width of the connecting portion 32 is greater than 1 micron.

FIG. 6B is a schematic diagram of another display panel according to an embodiment of the present disclosure. FIG. 6B merely schematically illustrates the film layer of the second electrodes 43 and the film layer of the light-shielding patterns 30 in the first display area AA1. FIG. 6B merely schematically illustrates the location of only one first virtual triangle 10. It can be seen from FIG. 6B that the area of the second electrode 43 is larger than the area of the main body portion 31 overlapping with the second electrode 43, and the line width of the electrode connecting line 46 is larger than the width of the connecting portion 32 overlapping with the electrode connecting line 46.

In an embodiment of the present disclosure, the second electrode 43 and the electrode connecting line 46 in the first display area AA1 are connected to each other to form a pattern having substantially the same shape as the light-shielding pattern 30. As seen in conjunction with FIGS. 3 and 4B, the first pixel column spL1 and second pixel column spL2 which are adjacent to each other along the second direction x constitute a pixel column group LZ, and the first virtual triangles 10 and the second virtual triangles 20 alternately arranged along the first direction y include two pixel column groups LZ. In the pixel row group LZ, the main body portions 31 corresponding to the sub-pixels sp are connected to one another in sequence via the connecting portions 32 along the first direction y. In the implementation, the main body portion 31 and the connecting portion 32 are connected to one another in sequence along the first direction y to form the light-shielding pattern 30 extending along the first direction y. When manufacturing the display panel, the light-shielding patterns 30 are used for shielding light to perform laser processing on the second electrode layer, and after a part of the second electrode layer is removed, the second electrodes 43 of the sub-pixels sp in the pixel row group LZ can be connected in sequence through the electrode connecting lines 46 along the first direction y, which ensures the electrical connection between the second electrodes 43 in the pixel row group LZ, and improves the transmittance of the first display area AA1. Moreover, in the implementation, the connecting portion 32 in the light-shielding pattern 30 is a strip-shaped structure extending substantially along the first direction y, and no connecting portion extending along the second direction x is provided, so that the light-shielding patterns 30, as a whole, occupy a relatively small area in the first display area AA1, and the transmittance of the first display area AA1 is significantly improved. When a photosensitive device is applied to the scheme of under-display photosensitive device, the diffraction of light along the first direction y can be improved, and the optical performance of the photosensitive device can be improved.

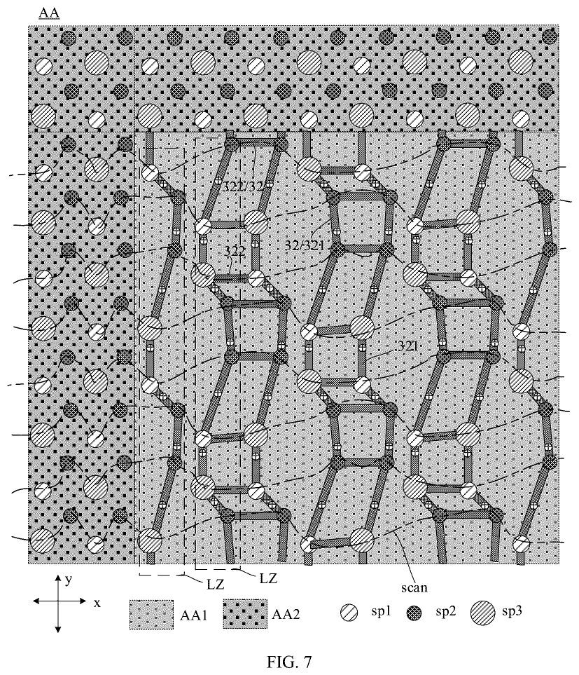

In other implementations, FIG. 7 is a schematic diagram of another display panel according to an embodiment of the present disclosure, and the main body portions 31 are not marked in the top view of FIG. 7. It can be understood that the main body portions 31 overlap with the sub-pixels sp. In the top view, the location of a sub-pixel sp is the location of the main body portions 31. As shown in FIG. 7, the first virtual triangles 10 and the second virtual triangles 20 which are alternately arranged along the first direction y include two pixel column groups LZ. In the pixel row group LZ, the main body portions 31 corresponding to the sub-pixels sp are connected in sequence by the connecting portions 32 along the first direction y. The connecting portions 32 includes a first connecting portion 321, and two sub-pixels sp corresponding to two main body portions 31 connected by the first connecting portion 321 are located in a same first pixel column spL1 or a same second pixel column spL2. The first pixel column spL1 and the second pixel column spL2 can be understood in conjunction with the illustration of FIG. 3. The included angle between the first connecting portion 321 and the first direction y is less than 10°. Some of the first connecting portions 321 are connected to two main body portions 31 corresponding to two second color sub-pixels sp2 which are adjacent to each other, and some of the first connecting portions 321 are connected to two main body portions 31 corresponding to one first color sub-pixel sp1 and one third color sub-pixel sp3 which are adjacent to each other. It can be understood that a main body portion 31 overlaps with a sub-pixel sp, a first connecting portion 321 is connected between two main body portions 31, and the extension line of the first connecting portion 321 may overlap with the center of the sub-pixel sp or be offset from the center of the sub-pixel sp. The included angle between the first connecting portion 321 and the first direction y is less than 10°, that is, the included angle between the connecting line between the two sub-pixels sp corresponding to the two main body portions 31 connected by the first connecting portion 321 and the first direction y is less than 10°.

In FIG. 7, it is also illustrated that the corresponding connections of the sub-pixels sp and the scan lines scan in the first display area AA1. The connecting portions 32 further includes a second connecting portion 322, two sub-pixels sp corresponding to two main body portions 31 connected by a second connecting portion 322 are connected to a same scan line scan, and an included angle between the second connecting portion 322 and the second direction x is less than 10°. Some of the second connecting portions 322 are connected to two main body portions 31 corresponding to two second color sub-pixels sp2 which are adjacent to each other, and some of the second connecting portions 322 are connected to two main body portions 31 corresponding to one first color sub-pixel sp1 and one third color sub-pixel sp3 which are adjacent to each other. The second connecting portions 322 are provided so that multiple connecting portions 32 intersect with each other to form a mesh structure at least in a partial region. Correspondingly, in the laser process, the light-shielding patterns are used to shield the laser, and the second electrodes 43 and the electrode connecting lines 46 intersect with each other to form a mesh a mesh structure in at least a portion of the region in the film layer in which the finally formed second electrodes are located. As a result, the overall voltage drop across the plurality of second electrodes 43 can be reduced, and the in-plane uniformity can be improved.

In some implementations, the included angle between the first connecting portion 321 and the first direction y is less than 5°, and the included angle between the second connecting portion 322 and the second direction x is less than 5°.

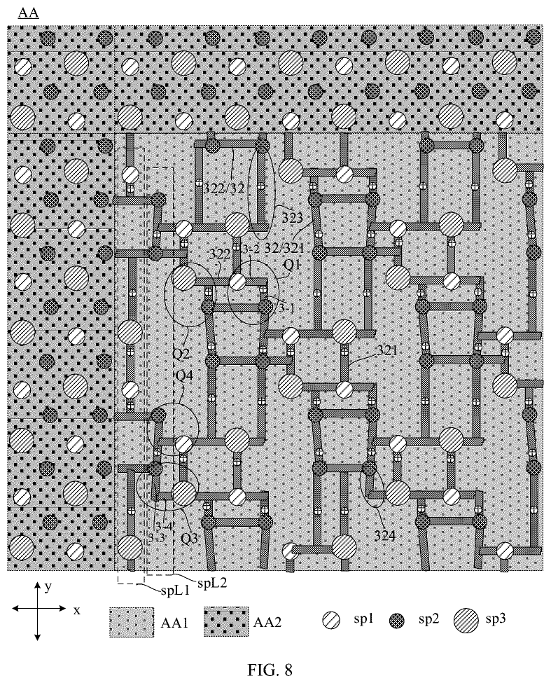

In some implementations, FIG. 8 is a schematic diagram of another display panel according to an embodiment of the present disclosure. As shown in FIG. 8, the connecting portions 32 further includes a third connecting portion 323. For example, at the location of the region Q1 in FIG. 8, the third connecting portion 323 includes a first connecting sub-portion 3-1 extending along the first direction y and a second connecting sub-portion 3-2 extending along the second direction x. Two sub-pixels sp corresponding to two main body portions 31 connected by the third connecting portion 323 are located in the first pixel column spL1 and the second pixel column spL2 which are adjacent to each other, and an included angle between a connecting line between the two sub-pixels sp and the first direction y is greater than 5°. For example, at the location of the region Q1, the second connecting sub-portion 3-2 overlaps with the extension line of the second connecting portion 322. For example, at the location of the region Q2, it is equivalent that the second connecting sub-portion 3-2 overlaps with the second connecting portion 322. For example, at the location of the region Q1, if no third connecting portion 323 is provided, and two main body portions 31 corresponding to two sub-pixels sp are directly connected merely by a connecting portion 32 extending obliquely, the connecting portion 32 would form a large angle at this location with the first direction y or the second direction x. According to the design of the embodiments of the present disclosure, the number of oblique connecting portions 32 in the first display area AA1 can be reduced, and the number of the first connecting sub-portions 3-1 extending along the first direction y and the number of the second connecting sub-portions 3-2 extending along the second direction x can be increased. When a photosensitive device is applied to the scheme of under-display photosensitive device, the diffraction of light along the second direction x and the first direction y can be improved, and the optical performance of the photosensitive device can be improved.

Further, for example, at the location of the region Q3 in FIG. 8, the connecting portions 32 further includes a fourth connecting portion 324, and the fourth connecting portion 324 includes a third connecting sub-portion 3-3 extending along the first direction y and a fourth connecting sub-portion 3-4 extending along the second direction x. Two sub-pixels sp corresponding to two main body portions 31 connected by the fourth connecting portion 3-4 are adjacent to each other along the second direction x, and are located in the first pixel column spL1 and the second pixel column spL2, respectively, and an included angle between a line connecting the two sub-pixels sp and the second direction x is greater than 5°. For example, at the location of the region Q3, the third connecting sub-portion 3-3 overlaps with the extension line of the first connecting portion 321. For example, at the location of the region Q4, the third connecting sub-portion 3-3 overlaps with the first connecting portion 321. For example, at the location of the region Q3, if no fourth connecting portion 324 is provided, and two main body portions 31 corresponding to two sub-pixels sp are directly connected merely by a connecting portion 32 extending obliquely, the connecting portion 32 would form a large angle at this location with the first direction y or the second direction x. According to the design of the embodiments of the present disclosure, the number of oblique connecting portions 32 in the first display area AA1 can be reduced, and the number of the third connecting sub-portions 3-3 extending along the first direction y and the number of the fourth connecting sub-portions 3-4 extending along the second direction x can be increased. When a photosensitive device is applied in the scheme of under-display photosensitive device, the diffraction of light along the second direction x and the first direction y can be improved, and the optical performance of the photosensitive device can be improved.

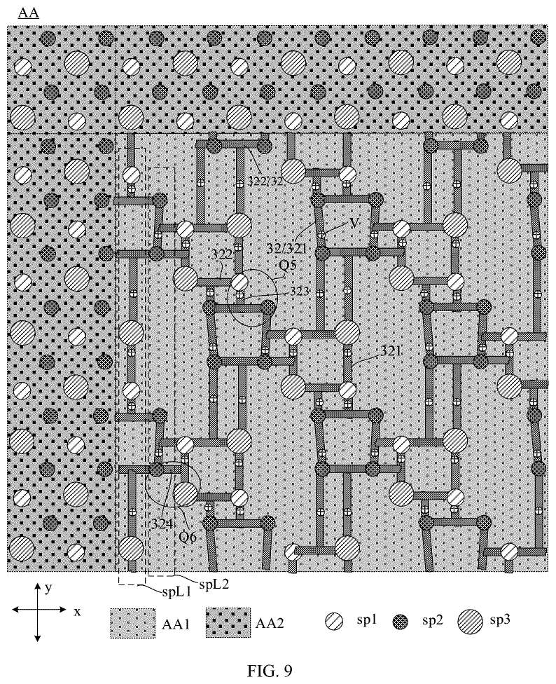

In some other implementations, FIG. 9 is a schematic diagram of another display panel according to an embodiment of the present disclosure. As shown in FIG. 9, the connecting portions includes a first connecting portion 321, a second connecting portion 322, a third connecting portion 323, and a fourth connecting portion 324. As can be seen in conjunction with FIG. 8, the third connecting portion 32 includes a first connecting sub-portion 3-1 extending along the first direction y and a second connecting sub-portion 3-2 extending along the second direction x. The location of the region Q5 in FIG. 9 and the location of the region Q1 in FIG. 8 are the same location. In FIG. 9, all the second connecting sub-portions 3-2 overlap with the second connecting portions 322, which is equivalent to reusing the second connecting portions 322 as the second connecting sub-portions 3-2. As can be seen in conjunction with FIG. 8, the fourth connecting portion 324 includes a third connecting sub-portion 3-3 extending along the first direction y and a fourth connecting sub-portion 3-4 extending along the second direction x. The location of the region Q6 in FIG. 9 and the location of the region Q3 in FIG. 8 are the same location. In FIG. 9, all the third connecting sub-portions 3-3 overlap with the first connecting portion 321, which is equivalent to reusing the first connecting portions 321 as the third connecting sub-portions 3-3. The embodiment shown FIG. 9 can reduce the total area occupied by the connecting portions 32 in the first display area AA1, which is beneficial to improving the transmittance of the first display area AA1.

In some implementations, as illustrated in the top view of FIG. 9, along the direction perpendicular to the plane of the substrate, the signal connection holes V overlap with the first connecting portions 321. In this way, the first signal lines X1 and the second signal lines X2 in the first display area AA1 can be arranged more regularly, so as to improve the utilization rate of the wiring space.

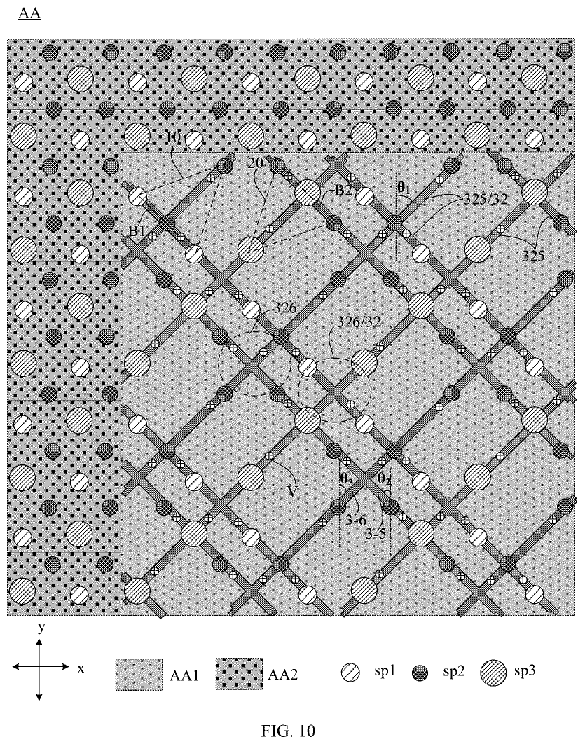

In some other implementations, FIG. 10 is a schematic diagram of another display panel according to an embodiment of the present disclosure, and the main body portions 31 are not marked in the top view of FIG. 10. It can be understood that a main body portions 31 overlaps with a sub-pixel sp. The location of the sub-pixel sp in the top view is the location of the main body portion 31. As shown in FIG. 10, a plurality of the connecting portions 32 include a plurality of fifth connecting portions 325 and a plurality of sixth connecting portions 326. A fifth connecting portions 325 is connected between two main body portions 31, and two sub-pixels sp corresponding to the two main body portions 31 connected by the one fifth connecting portion 325 are located in a same first virtual triangle 10 or a same second virtual triangle 20. The sixth connecting portions 326 is in a cross shape, a sixth connecting portion 326 is connected between four main body portions 31, and four sub-pixels sp corresponding to the four main body portions 31 connected by the sixth connecting portion 326 are located in two first virtual triangles 10 and two second virtual triangles 20. For example, the sixth connecting portions 326 includes a fifth connecting sub-portion 3-5 and a sixth connecting sub-portion 3-6, and the fifth connecting sub-portion 3-5 and the sixth connecting sub-portion 3-6 intersect with each other to form a cross shape. In an embodiment of the present disclosure, the three sides of the first virtual triangle 10 forms a non-zero included angle with the first direction y, respectively, and the three sides of the second virtual triangle 20 forms a non-zero included angle with the first direction y, respectively. Accordingly, the fifth connecting portion 325 and the sixth connecting portion 326 are both oblique connecting portions. In an implementation, the fifth connecting portions 325, the sixth connecting portions 326 and the plurality of main body portions 31 are connected to each other to form a mesh structure, and in the laser process, correspondingly, the light-shielding patterns are used to shield the laser, and the second electrodes 43 and the electrode connecting lines 46 intersect with each other to form a mesh a mesh structure in at least a portion of the region in the film layer in which the finally formed second electrodes are located. As a result, the overall voltage drop across the plurality of second electrodes 43 can be reduced, and the in-plane uniformity can be improved. When a photosensitive device is applied to the scheme of under-display photosensitive device, the oblique diffraction of light can be improved, and the optical performance of the photosensitive device can be improved.

In an embodiment, as shown in FIG. 10, in the first virtual triangle 10, two main body portions 31 corresponding to two second color sub-pixels sp2 are connected to each other by the fifth connecting portion 325, and two main body portions 31 corresponding to the first color sub-pixel sp1 and the second color sub-pixel sp2 which are adjacent to each other and located on the first side B1 are connected to each other by the fifth connecting portion 325. In the second virtual triangle 20, two main body portions 31 corresponding to two third color sub-pixels sp3 are connected to each other by the fifth connecting portion 325, and two main body portions 31 corresponding to the third color sub-pixel sp3 and the second color sub-pixel sp2 which are adjacent to each other and located on the second side B2 are connected to each other by the fifth connecting portion 325.

As shown in FIG. 10, an included angle between the fifth connecting portions 325 and the first direction y is θ₁, where 40°≤η₁≤50°. The sixth connecting portions 326 comprises a fifth connecting sub-portion 3-5 and a sixth connecting sub-portion 3-6. The fifth connecting sub-portion 3-5 and the sixth connecting sub-portion 3-6 intersect with each other to form a cross shape. An included angle between the fifth connecting sub-portion 3-5 and the first direction y is θ₂, where 40°≤θ₂≤50°. An included angle between the sixth connecting sub-portion 3-6 and the first direction y is θ₃, where 40°≤θ₃≤50°. The included angles mentioned above all refer to acute included angles. The fifth connecting portion 325, the fifth connecting sub-portion 3-5, and the sixth connecting sub-portion 3-6 each are connected between two main body portions 31, and the main body portion 31 needs to overlap with the sub-pixel sp. That is, the location of the sub-pixel sp limits the location of the main body portion 31, and thus affects the extending direction of the connecting portion between two main body portions 31. In an embodiment of the present disclosure, the ranges of the angles mentioned above is limited, which enables the connecting portions are designed to match with the arrangement mode of the sub-pixels sp in the first display area AA1, and the total area occupied by the connecting portions is reduced as much as possible, so as to improve the transmittance of the first display area AA1.

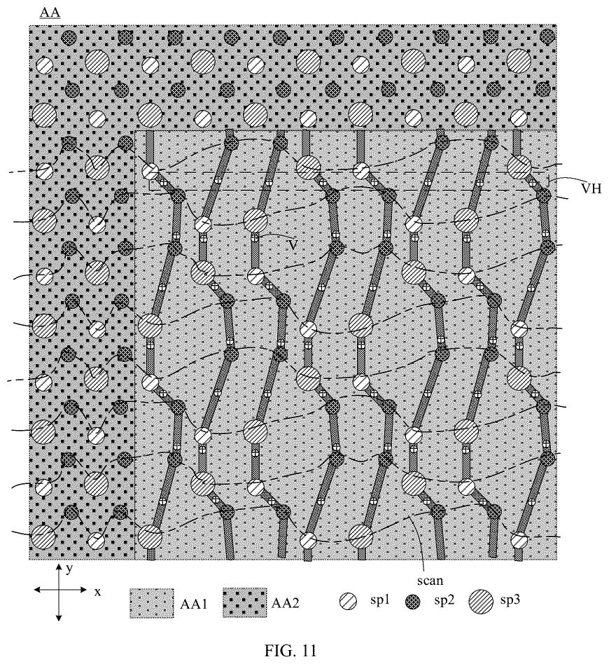

In some implementations, FIG. 11 is a schematic diagram of another display panel according to an embodiment of the present disclosure, and the connecting portions in FIG. 11 is shown in the shape of FIG. 4B. As shown in FIG. 11, in the first display area AA1, a plurality of signal connection holes V are arranged along the second direction x to form a plurality of signal hole rows VH arranged along the second direction x. In this way, the arrangement regularity of the first signal lines X1 and the second signal lines X2 in the first display area AA1 is enhanced, and the utilization rate of the wiring space is improved.

FIG. 11 also illustrates the scan lines scan are connected to the sub-pixels sp in the first display area AA1. A plurality of pixel circuits 44 corresponding to a plurality of signal connection holes V in one signal hole row VH are connected to a same scan line scan. That is, the sub-pixels sp corresponding to the plurality of signal connection holes V in one signal hole row VH are connected to a same scan line scan. For example, for one signal hole row VH, a first signal line X1 connected to a signal connection hole V is pulled upward (referring to up and down in the paper illustrated in FIG. 11) to connect to a row of sub-pixels sp above the signal hole row VH. In this way, the arrangement regularity of the first signal lines X1 and the second signal lines X2 in the first display area AA1 is enhanced, the signal line winding is reduced, and the utilization rate of the wiring space is improved.

In some implementations, a plurality of sub-pixels sp corresponding to a plurality of signal connection holes V in one signal hole row VH are located on a same side of the signal hole row VH. For example, in the paper illustrated in FIG. 11, a plurality of signal connection holes V in a signal hole row VH can be correspondingly connected to a row of sub-pixels sp above the signal hole row VH, or a plurality of signal connection holes V in a signal hole row VH can be correspondingly connected to a row of sub-pixels sp below the signal hole row VH. In this way, the arrangement regularity of the first signal lines X1 and the second signal lines X2 in the first display area AA1 is enhanced, the signal line winding is reduced, and the utilization rate of the wiring space is improved.

In some implementations, in the first display area AA1, a spacing between any two adjacent signal hole rows VH along the first direction y is equal to each other. The overall arrangement of the plurality of signal connection holes V in the first display area AA1 is more regular, and thus the arrangement of the first signal lines X1 connected to the signal connection holes V and the second signal lines X2 connected to the signal connection holes is also more regular, which is beneficial to improving the overall space utilization rate of the first display area AA1.

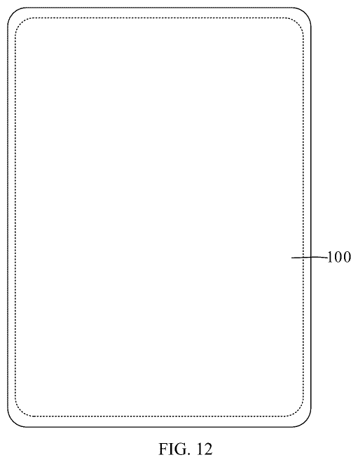

Based on the same inventive concept, an embodiment of the present disclosure further provides a display apparatus, and FIG. 12 is a schematic diagram of the display apparatus according to an embodiment of the present disclosure. As shown in FIG. 12, the display apparatus includes a display panel 100 according to any embodiment of the present disclosure. The method for driving the display panel has been described in the above-mentioned embodiments, and will not repeatedly described herein. The display apparatus according to an embodiment of the present disclosure may be, for example, an electronic device with a display function such as a mobile phone, a tablet, a computer, a television, and a smart wearable product.

The above descriptions are merely preferred embodiments of the present disclosure and are not intended to limit the present disclosure. Any modification, equivalent replacement and improvement within the spirit and principle of the present disclosure shall be comprised within the protection scope of the present disclosure.

Finally, it should be noted that the above embodiments are merely used to illustrate the technical solutions of the present disclosure, not to limit the present disclosure. Although the present disclosure has been described in detail with reference to the foregoing embodiments, those skilled in the art should understand that the technical solutions described in the foregoing embodiments can still be modified, or some or all of the technical features thereof can be equivalently replaced; and these modifications or replacements do not cause the essence of the corresponding technical solutions to depart from the scope of the technical solutions of the embodiments of the present disclosure.

What is claimed is:

1. A display panel, comprising:
a plurality of sub-pixels comprising first color sub-pixels, second color sub-pixels and third color sub-pixels; and
a display area comprising a first display area and a second display area, wherein a transmittance of the first display area is greater than a transmittance of the second display area;
wherein the first display area has first virtual triangles and second virtual triangles, and wherein in the first display area:
two of the first color sub-pixels and one of the second color sub-pixels are provided at three vertexes of one of the first virtual triangles, and another one of the second color sub-pixels is provided on a first side between the two first color sub-pixels in the one of the first virtual triangles; and an angle opposite to the first side in the one of the first virtual triangles is a first angle;
two of the second color sub-pixels and one of the third color sub-pixels are provided at three vertexes of one of the second virtual triangles, and another one of the third color sub-pixels is provided on a second side between the two second color sub-pixels in the one of the second virtual triangles; an angle opposite to the second side in the one of the second virtual triangles is a second angle; and an orientation of the second angle is opposite to an orientation of the first angle; and
the first virtual triangles and the second virtual triangles are alternately arranged in a first direction, the first virtual triangles and the second virtual triangles are alternately arranged in a second direction, and the first direction and the second direction intersect with each other.

2. The display panel according to claim 1, further comprising a plurality of data lines, wherein
in the first display area, the first color sub-pixels and the third color sub-pixels are alternately arranged along the first direction to form first pixel columns, the second color sub-pixels are arranged along the first direction to form second pixel columns, and the first pixel columns and the second pixel columns are alternately arranged in the second direction; and
the first color sub-pixels and the third color sub-pixels in at least one of the first pixel columns are electrically connected to a same data line, and the second color sub-pixels in at least one of the second pixel columns are electrically connected to another same data line.

3. The display panel according to claim 2, further comprising a plurality of scan lines, wherein the plurality of scan lines comprise first scan lines and second scan lines, and the plurality of sub-pixels on the first virtual triangles and the second virtual triangles alternately arranged in the second direction are connected to one of the first scan lines and one of the second scan lines;
one of the two first color sub-pixels located on the first side, the one second color sub-pixel located on the first angle, one of the two second color sub-pixels located on the second side, and the one third color sub-pixel located on the second side are electrically connected to the one first scan line in sequence; and
the one second color sub-pixel located on the first side, the other one of the two first color sub-pixel located on the first side, the one third color sub-pixel located on the second angle, and the other one of the two second color sub-pixel located on the second side are electrically connected to the one second scan line in sequence.

4. The display panel according to claim 2, further comprising a substrate, wherein
at least one of the plurality of sub-pixels comprises a first electrode stacked on the substrate, a light-emitting layer and a second electrode at a side, away from the substrate, of the first electrode; and
the first display area comprises light-shielding patterns at a side of one of the plurality of sub-pixels close to the substrate, at least one of the light-shielding patterns comprises a main body portion and a connecting portion, the main body portion overlaps with the light-emitting layer along a direction perpendicular to a plane of the substrate, and at least one of a plurality of connecting portions is connected between at least two of a plurality of main body portions.

5. The display panel according to claim 4, further comprising a plurality of pixel circuits, wherein
the display area further comprises a transition area provided between the first display area and the second display area; and
the plurality of pixel circuits are provided at a side of the light-shielding patterns away from the substrate, one of the plurality of pixel circuits is electrically connected to at least one sub-pixel, and pixel circuits electrically connected to sub-pixels in the first display area are arranged in the transition area;
wherein the sub-pixels in the first display area are electrically connected to the pixel circuits via signal connection holes; and along the direction perpendicular to the plane of the substrate, the signal connection holes overlap with the connecting portions.

6. The display panel according to claim 4, wherein
the first display area comprises electrode connecting lines, at least one of the electrode connecting lines is located on a same layer with the second electrode and is connected to the second electrode; and along the direction perpendicular to the plane of the substrate, the second electrode overlaps with at least one of the main body portions, and at least one of the electrode connecting lines overlaps with at least one of the connecting portions; and
in the first display area, orthographic projections of the second electrode and the at least one of the electrode connecting lines on a film layer of at least one light-shielding pattern cover the at least one light-shielding pattern.

7. The display panel according to claim 4, wherein
one of the first pixel columns and one of the second pixel columns adjacent to each other in the second direction constitute a pixel column group, and the first virtual triangles and the second virtual triangles alternately arranged along the first direction include two pixel column groups; and
a plurality of the main body portions corresponding to a plurality of sub-pixels in the pixel array group are connected in sequence to one another through the connecting portions along the first direction.

8. The display panel according to claim 7, further comprising a plurality of scan lines, wherein
the plurality of sub-pixels are electrically connected to the plurality of scan lines;
the connecting portions comprise a first connecting portion, two sub-pixels corresponding to two main body portions connected by the first connecting portion are located in a same first pixel column or a same second pixel column, and an included angle between the first connecting portion and the first direction is less than 10°; and the connecting portions further comprise a second connecting portion, two sub-pixels corresponding to two main body portions connected by the second connecting portion are connected to a same scan line, and an included angle between the second connecting portion and the second direction is less than 10°.

9. The display panel according to claim 8, wherein
the connecting portions further comprise a third connecting portion, the third connecting portion comprises a first connecting sub-portion extending along the first direction and a second connecting sub-portion extending in the second direction; two sub-pixels corresponding to two main body portions connected by the third connecting portion are respectively located in one of the first pixel columns and one of the second pixel columns which are adjacent to each other, and an included angle between a connecting line between the two sub-pixels and the first direction is greater than 5°; and the second connecting sub-portion overlaps with the second connecting portion or overlaps with an extension line of the second connecting portion.

10. The display panel according to claim 8, wherein
the connecting portions further comprise a fourth connecting portion, the fourth connecting portion comprises a third connecting sub-portion extending along the first direction and a fourth connecting sub-portion extending in the second direction; two sub-pixels corresponding to two main body portions connected by the fourth connecting portion are respectively located in one of the first pixel columns and one of the second pixel columns which are adjacent to each other, and an included angle between a connecting line between the two sub-pixels and the second direction is greater than 5°; and the third connecting sub-portion overlaps with the first connecting portion or overlaps with an extension line of the first connecting portion.

11. The display panel according to claim 8, wherein the first display area further comprises signal connection holes; and along the direction perpendicular to the plane of the substrate, at least one of the signal connection holes overlap with the first connecting portion.

12. The display panel according to claim 4, wherein
the plurality of connecting portions comprise a plurality of fifth connecting portions and a plurality of sixth connecting portions; at least one of the fifth connecting portions is connected between two main body portions, and two sub-pixels corresponding to the two main body portions connected by the at least one of the fifth connecting portions are located in a same first virtual triangle or a same second virtual triangle; and
at least one of the sixth connecting portions is cross-shaped and connected among four main body portions, and four sub-pixels corresponding to the four main body portions connected by the at least one of the sixth connecting portions are located in two first virtual triangles and two second virtual triangles.

13. The display panel according to claim 12, wherein
in the first virtual triangles, two main body portions corresponding to two second color sub-pixels are connected by one of the fifth connecting portions, and two main body portions corresponding to one of the first color sub-pixels and one of the second color sub-pixels, which are adjacent to each other and located on the first side, are connected by one of the fifth connecting portions; and
in the second virtual triangles, two main body portions corresponding to two third color sub-pixels are connected by one of the fifth connecting portions, and two main body portions corresponding to one of the third color sub-pixels and one of the second color sub-pixels, which are adjacent to each other and located on the second side, are connected by at least one of the fifth connecting portions.

14. The display panel according to claim 12, wherein
an included angle between a fifth connecting portion and the first direction is θ₁, where 40°≤θ₁≤50°; and
at least one of the sixth connecting portions comprises a fifth connecting sub-portion and a sixth connecting sub-portion, the fifth connecting sub-portion and the sixth connecting sub-portion intersect with each other to form a cross shape, an included angle between the fifth connecting sub-portion and the first direction is θ₂, where 40°<θ₂<50°, and an included angle between the sixth connecting sub-portion and the first direction is θ₃, where 40°≤θ₃≤50°.

15. The display panel according to claim 5, wherein
the first display area comprises a first signal line and a second signal line, the first signal line and the first electrode are connected to each other and located on a same layer, a material of the second signal line comprises a transparent material, one end of the second signal line is electrically connected to the first signal line through at least one of the signal connection holes, and the other end of the second signal line is connected to one of the pixel circuits; and
along the direction perpendicular to the plane of the substrate, the first signal line overlaps with one of the connecting portions.

16. The display panel according to claim 5, wherein
in the first display area, the signal connection holes are arranged along the second direction to form signal hole rows, and the signal hole rows are arranged along the first direction.

17. The display panel according to claim 16, further comprising a plurality of scan lines, wherein
one of the plurality of scan lines is connected to the pixel circuits; and
pixel circuits corresponding to signal connection holes in one signal hole row are connected to a same scan line.

18. The display panel according to claim 16, wherein
sub-pixels corresponding to signal connection holes in one signal hole row are located on a same side of the signal hole row.

19. The display panel according to claim 16, wherein
in the first display area, a spacing between any two adjacent signal hole rows along the first direction are equal to each other.

20. A display apparatus comprising a display panel comprising:
a plurality of sub-pixels comprising first color sub-pixels, second color sub-pixels and third color sub-pixels; and
a display area comprising a first display area and a second display area, wherein a transmittance of the first display area is greater than a transmittance of the second display area;
wherein the first display area has first virtual triangles and second virtual triangles, and wherein in the first display area:
two of the first color sub-pixels and one of the second color sub-pixels are provided at three vertexes of one of the first virtual triangles, and another one of the second color sub-pixels is provided on a first side between the two first color sub-pixels in the one of the first virtual triangles; and an angle opposite to the first side in the one of the first virtual triangles is a first angle;
two of the second color sub-pixels and one of the third color sub-pixels are provided at three vertexes of one of second virtual triangles, and another one of the third color sub-pixels is provided on a second side between the two second color sub-pixels in the one of the second virtual triangles; an angle opposite to the second side in the one of the second virtual triangles is a second angle; and an orientation of the second angle is opposite to an orientation of the first angle; and
the first virtual triangles and the second virtual triangles are alternately arranged in a first direction, the first virtual triangles and the second virtual triangles are alternately arranged in a second direction, and the first direction and the second direction intersect with each other.
